(19) United States
(12) Patent Application Publication
(10) Pub. No.: US 2002/0003267 A1
(43) Pub. Date: Jan. 10, 2002

(54) GATE ELECTRODE HAVING AGGLOMERATION PREVENTING LAYER ON METAL SILICIDE LAYER, AND METHOD FOR FORMING THE SAME

(76) Inventors: EUN-HA LEE, CHUNGCHEONGNAM-DO (KR); KEUNG-HEE JANG, KYUNGKI-DO (KR); BYUNG-CHAN LEE, KYUNGKI-DO (KR)

Correspondence Address: DAVID T MILLERS, SKJERVEN MORRILL MACPHERSON, FRANKLIN & FRIEL LLP, 25 METRO DRIVE SUITE 700, SAN JOSE, CA, 951101349

(21) Appl. No.: 09/357,464

(22) Filed: Jul. 20, 1999

(30) Foreign Application Priority Data
Jul. 22, 1998 (KR) 1998-29530

(51) Int. Cl. H01L 29/76; H01L 31/119; H01L 31/113

(52) U.S. Cl. 257/388

(57) ABSTRACT

A gate electrode having an agglomeration preventing layer formed on a metal silicide layer is disclosed. The agglomeration preventing layer prevents the metal silicide layer from agglomerating. The gate electrode in accordance with an embodiment of the present invention includes a gate dielectric film formed on a semiconductor substrate, an impurity-doped polysilicon layer formed on the gate dielectric film, a metal silicide layer formed on the polysilicon layer, a titanium nitride (TiN) barrier layer formed between the polysilicon layer and the metal silicide layer, and the agglomeration prevention layer formed on the metal silicide layer. The agglomeration preventing layer can be a TiN layer or TiSiN layer. In addition, a method for forming the gate electrode is also disclosed.

### BACKGROUND OF THE INVENTION

1. Field of the Invention The present invention relates to a semiconductor device and a manufacturing method therefor, and more particularly, to a gate electrode using a metal silicide layer as a conductive layer.

2. Description of the Related Art Higher semiconductor device integration results in smaller line widths of gate lines and thus higher gate line resistances. To overcome this, research has been conducted into methods for forming gate electrodes using materials with a low resistivity. As a result, a polycide structure having a metal silicide layer on an impurity-doped polysilicon layer has been widely used for a gate structure. In particular, since a gate electrode having a titanium polycide structure has a very low resistance, the titanium polycide structure can reduce both the resistance of a gate line and a step difference in the gate electrode. Thus, gate electrodes having the titanium polycide structure can be favorably applied to a highly integrated device such as 1G DRAM.

However, with a very narrow gate line, a titanium silicide layer agglomerates when heated. Such agglomeration of the titanium silicide layer directly increases resistance in gate lines.

A conventional method suppresses agglomeration of the titanium silicide layer by interposing a TiN barrier layer between a polysilicon layer and a titanium silicide layer. (See Dae-Lok Bae et al., “Reliability and Electrical Properties of Poly-Si/TiSix Gate Structure with TiN Barrier Layers”, Advanced Metallization and Interconnection Systems for ULSI Applications, 1995, pp 363-368). The TiN barrier layer increases an interface energy between the titanium silicide layer and the polysilicon layer and helps suppress the agglomeration of the titanium silicide layer and thereby keeps the resistance in the gate line low.

However, the conventional method is only effective for gate lines having line widths of 0.3μm or more. When the gate line is 0.3μm or less, the metal silicide layer is liable agglomerate, even though the TiN barrier layer is between the polysilicon layer and the metal silicide layer, and the agglomeration increases gate resistance.

### SUMMARY OF THE INVENTION

A semiconductor gate electrode that can prevent an agglomeration of a metal silicide layer in a very narrow (0.3μm or less) gate line and a method for forming the gate electrode are disclosed.

According to an embodiment of the present invention, a semiconductor gate electrode includes: a gate dielectric film on a semiconductor substrate; a doped polysilicon layer on the gate dielectric film; a metal silicide layer on the polysilicon layer; a titanium nitride (TiN) barrier layer between the polysilicon layer and the metal silicide layer; and an agglomeration prevention layer on the metal silicide layer to suppress an agglomeration of the metal silicide layer. The agglomeration preventing layer is preferably a TiN layer or TiSiN layer, and has a thickness of 500Å or less. The metal silicide layer can be formed of titanium silicide, tungsten silicide, cobalt silicide, molybdenum silicide or tantalum silicide. The gate electrode can further include an insulation layer covering the agglomeration preventing layer.

According to another embodiment of the present invention, a method for forming a semiconductor gate electrode includes: forming a gate dielectric film on a semiconductor substrate; forming an impurity-doped polysilicon layer on the gate dielectric film; forming a titanium nitride (TiN) barrier layer on the impurity-doped polysilicon layer; forming a metal silicide layer on the TiN barrier layer; forming an agglomeration preventing layer on the metal silicide layer to prevent an agglomeration of the metal silicide layer; forming a hard mask pattern on the agglomeration preventing layer; patterning in sequence the agglomeration preventing layer, the metal silicide layer, the TiN barrier layer and the polysilicon layer using the hard mask pattern as an etching mask to form a gate pattern; and forming spacers formed of an insulation layer on the side walls of the gate pattern.

The metal silicide layer can include titanium silicide, tungsten silicide, cobalt silicide, molybdenum silicide or tantalum silicide. The agglomeration preventing layer can include TiN or TiSiN and can be formed by a sputtering or chemical vapor deposition (CVD). Alternatively, the forming of the agglomeration preventing layer includes treating the metal suicide layer with NH₃ plasma. The hard mask pattern is formed of an oxide layer, a nitride layer or a stacked layer including the oxide and nitride layers.

### BRIEF DESCRIPTION OF THE DRAWINGS

The advantages of the present invention will become more apparent by describing in detail embodiments thereof with reference to the attached drawings in which:

FIGS. 1A through 1E are sectional views of semiconductor structures illustrating a method for forming a semiconductor gate electrode according to an embodiment of the present invention; and

FIG. 2 is a graph showing the effect of an agglomeration preventing layer on the sheet resistance of a gate electrode.

### DESCRIPTION OF THE PREFERRED EMBODIMENT

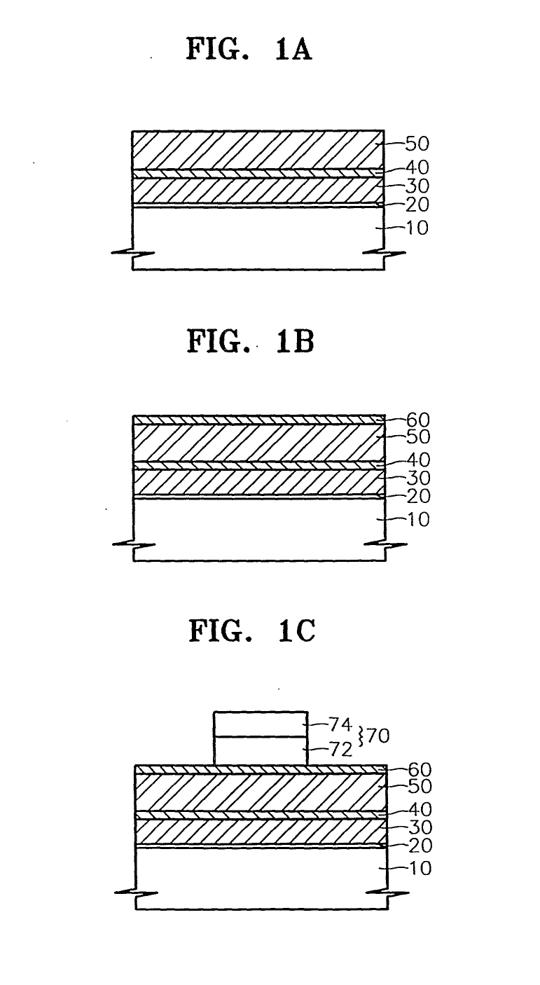

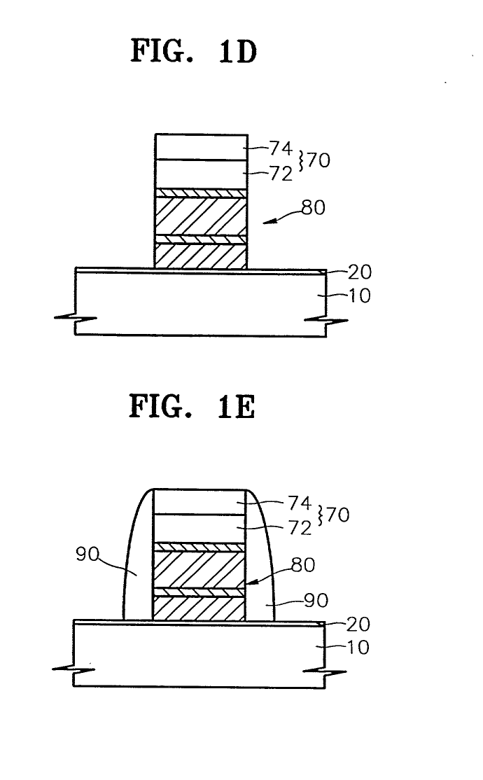

Referring to FIG. 1A, a gate dielectric film 20 is formed on a semiconductor substrate 10, and then an impurity-doped polysilicon layer 30 is formed thereon. Then, a TiN barrier layer 40 is formed on the polysilicon layer 30 to a thickness of about 500Å or less. The TiN barrier layer 40 prevents diffusion of material from a metal silicide layer 50 to be formed in a subsequent step into the gate dielectric film 20. For example, assuming that a titanium silicide layer is formed in a subsequent step, the TiN barrier layer 40 prevents diffusion of titanium from the titanium silicide layer into a gate oxide layer.

For example, to form metal silicide layer 50 on TiN barrier layer 40, a polysilicon layer and a refractory metal layer made of titanium (Ti), tungsten (W), cobalt (Co), molybdenum (Mo) or tantalum (Ta) are formed on TiN barrier layer 40, and then annealed. Alternatively, sputtering or chemical vapor deposition (CVD) can directly form metal silicide layer 50 on TiN barrier layer 40.

The metal silicide layer 50 can be formed of titanium silicide, tungsten silicide, cobalt silicide, molybdenum silicide or tantalum silicide, and titanium silicide is preferred. When the metal silicide layer 50, in particular, a titanium silicide layer, is annealed in a subsequent step, the titanium silicide layer tends to agglomerate to lower grain boundary energy in the titanium suicide layer. Moreover, if the line width of a gate line is 0.3μm or less, e.g., approximately 0.17μm, agglomeration of the metal suicide layer is prone to occur despite barrier layer 40. According to an aspect of the present invention, increasing the interface energy between the titanium silicide layer and an upperlayer combined with increasing the interface energy between the titanium suicide layer and the underlayer suppresses agglomeration of the titanium silicide layer, caused by subsequent annealing.

Referring to FIG. 1B, an agglomeration preventing layer 60 is formed of TiN or TiSiN on the metal silicide layer 50 to a thickness of 500Å or less. The agglomeration preventing layer 60 increases the interface energy with the metal silicide layer 50, thereby suppressing agglomeration of the metal silicide layer 50 during a following annealing step. The agglomeration preventing layer 60 can be formed by sputtering or CVD. Another method for forming the agglomeration preventing layer 60 forms a titanium silicide layer as the metal silicide layer 50 and then treats the titanium silicide layer with a NH₃ plasma, thereby forming the agglomeration preventing layer 60 of TiN or TiSiN on the titanium silicide layer.

Referring to FIG. 1C, a hard mask pattern 70 is formed on the agglomeration preventing layer 60. The hard mask pattern 70 can be an oxide layer, a nitride layer or a stacked layer of the two. In forming the hard mask pattern 70, a silicon nitride layer and a silicon dioxide layer are formed in sequence on the agglomeration preventing layer 60, and then patterned to form a silicon nitride layer pattern 72 and a silicon dioxide layer pattern 74, which form the hard mask pattern 70.

Referring to FIG. 1D, in order to form a gate pattern 80, an etching process patterns in sequence the agglomeration preventing layer 60, the metal silicide layer 50, the TiN barrier layer 40 and the polysilicon layer 30 using the hard disk mask 70 as an etching mask.

Referring to FIG. 1E, a dielectric layer is deposited on gate pattern 80 and then etched back to form spacers 90 on side walls of gate pattern 80 and hard mask pattern 70. Spacer 90 can be formed from an oxide layer, a nitride layer or a stacked layer of the two. For example, to form spacer 90, a silicon nitride layer is formed on gate pattern 80 and anisotropically etched back to form a first spacer on the side walls of gate pattern 80 and hard mask pattern 70. A silicon dioxide layer is then formed on the structure including the first spacer and etched back to form a second spacer on the first spacer. The resulting spacer 90 has the silicon nitride layer and the silicon dioxide layer stacked in sequence. Alternatively, forming a silicon nitride layer and a silicon dioxide layer in sequence on gate pattern 80 and etching back the layers can form a stacked spacer 90 on the side walls of gate pattern 80 and hard mask pattern 70.

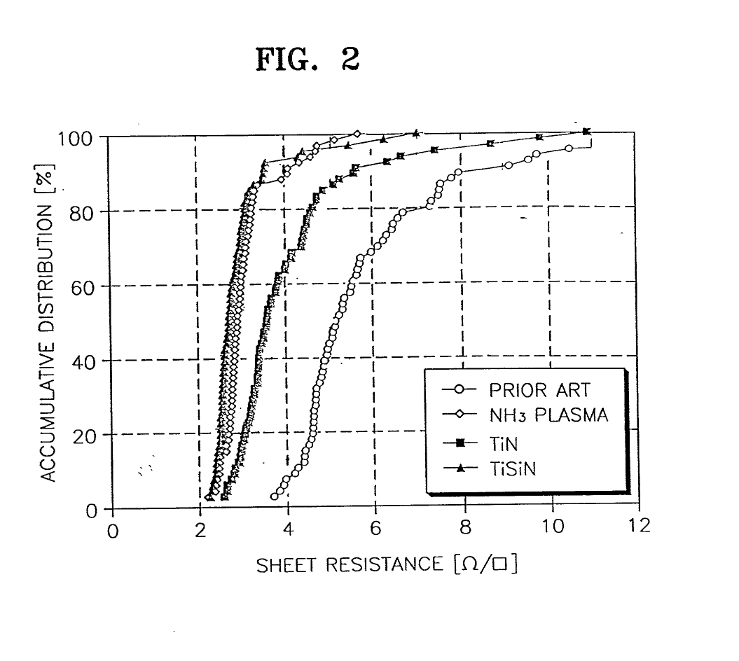

FIG. 2 is a graph comparatively showing accumulative distributions in sheet resistance characteristics of gate electrodes having an agglomeration preventing layer on a titanium silicide layer according to the present invention and a conventional gate electrode without the agglomeration preventing layer. Here, the gate electrodes had a titanium polycide structure and the line width of 0.17μm. Gate electrodes having three different agglomeration preventing layers were tested: a 100Å thick TiN agglomeration preventing layer (-▪-) formed by sputtering, a 100Å thick TiSiN agglomeration preventing layer (-Δ-) formed by sputtering, and an agglomeration preventing layer (-⋄-) formed by treating a titanium silicide layer with a NH₃ plasma. A conventional gate electrode (-O-) having no agglomeration preventing layer was also tested. Before the test, the four gate electrodes were annealed.

Referring to FIG. 2, it is obvious that the gate electrodes having the agglomeration preventing layers have better sheet resistance than the conventional gate electrode without the agglomeration preventing layer. That is, the agglomeration preventing layers on the titanium silicide layer according to the present invention effectively suppressed the agglomeration of the titanium silicide layer and kept the sheet resistance of the gate electrodes having the agglomeration preventing layers lower than that of the gate electrode without the agglomeration preventing layer.

As described above, a TiN barrier layer is formed between a polysilicon layer and a metal silicide layer in a polycide structure, and an agglomeration preventing layer, which is made of TiN or TiSiN, is formed on the metal silicide layer which is used as a conductive layer in a semiconductor device. The agglomeration preventing layer increases an interface energy between the metal silicide layer and the agglomeration preventing layer, so as to prevent an agglomeration of the metal silicide layer when a line width of a gate line is 0.3μm or less.

Although the invention has been described with reference to particular embodiments, the description is an example of the invention'application and should not be taken as a limitation. Various adaptations and combinations of the features of the embodiments disclosed are within the scope of the invention as defined by the following claims.

What is claimed is:

1. A gate electrode of a semiconductor device, comprising:
a gate dielectric film on a semiconductor substrate;
a doped polysilicon layer on the gate dielectric film;
a metal silicide layer on the polysilicon layer;
a titanium nitride (TiN) barrier layer between the polysilicon layer and the metal silicide layer; and
an agglomeration prevention layer on the metal silicide layer.

2. The gate electrode of claim 1, wherein the agglomeration preventing layer comprises a material selected from a group consisting of TiN and TiSiN.

3. The gate electrode of claim 1, wherein the agglomeration preventing layer has a thickness of 500Å or less.

4. The gate electrode of claim 1, wherein the metal silicide layer is formed of a material selected from a group consisting of titanium silicide, tungsten silicide, cobalt silicide, molybdenum silicide and tantalum silicide.

5. The gate electrode of claim 1, further comprising an insulation layer covering the agglomeration preventing layer.

6. A method for forming a gate electrode of a semiconductor device, comprising:
(a) forming a gate dielectric film on a semiconductor substrate;
(b) forming an impurity-doped polysilicon layer on the gate dielectric film;
(c) forming a titanium nitride (TiN) barrier layer on the impuritydoped polysilicon layer;
(d) forming a metal silicide layer on the TiN barrier layer;
(e) forming an agglomeration preventing layer on the metal silicide layer;
(f) forming a hard mask pattern on the agglomeration preventing layer; and
(g) patterning the agglomeration preventing layer, the metal silicide layer, the TiN barrier layer and the polysilicon layer in sequence using the hard mask pattern as an etching mask to form a gate pattern.

7. The method of claim 6, wherein the metal silicide layer is formed of a material selected from a group consisting of titanium silicide, tungsten silicide, cobalt silicide, molybdenum silicide and tantalum silicide.

8. The method of claim 6, wherein a sputtering forms the agglomeration preventing layer.

9. The method of claim 6, wherein the agglomeration preventing layer comprises a material selected from a group consisting of TiN and TiSiN.

10. The method of claim 6, wherein the agglomeration preventing layer has a thickness of 500Å or less.

11. The method of claim 6, wherein the forming the agglomeration preventing layer comprises treating the metal silicide layer with a NH₃ plasma.

12. The method of claim 6, wherein the hard mask pattern comprises a layer selected from a group consisting of an oxide layer, a nitride layer and stacked layers including the oxide and nitride layers.

13. The method of claim 6, wherein a chemical vapor deposition (CVD) forms the agglomeration preventing layer.

14. The method of claim 6, further comprising forming spacers as an dielectric layer on side walls of the gate pattern.
